(19) United States
(12) Patent Application Publication
(10) Pub. No.: US 2011/0236591 A1
(43) Pub. Date: Sep. 29, 2011

(54) BIPOLAR RECTIFIER POWER SUPPLY

(75) Inventors: John E. Madocks, Tucson, AZ (US); Curtis Charles Camus, Tucson, AZ (US); Patrick Marcus, Tucson, AZ (US)

(73) Assignee: General Plasma INc., Tucson, AZ (US)

(21) Appl. No.: 13/131,649

(22) PCT Filed: Nov. 30, 2009
(86) PCT No.: PCT/US09/66108

§ 371 Date: May 27, 2011

Related U.S. Application Data
(60) Provisional application No. 61/118,579, filed on Nov. 28, 2008.

(51) Int. Cl. C23C 14/35; H02M 7/217; H05H 1/46

(52) U.S. Cl. 427/523; 363/89; 363/127; 427/569

(57) ABSTRACT

A process for powering an electrical load includes applying a rectified alternating current waveform across the load for a first time period with only a single power supply for at least two half cycles. At least one half cycle of an alternating current waveform of opposite polarity are then applied relative to the rectified alternating current waveform across the load for a second time period. Rectified alternating current waveform is then again applied across the load for at least two half cycles for a third time period to power the electrical load. The rectified alternating current waveform can be applied a direct current offset. A power supply is provided for provided power across the load according to this process.

### CROSS-REFERENCE TO RELATED APPLICATIONS

This application claims priority benefit of U.S. Provisional Application 61/118,579 filed Nov. 28, 2008, the contents of which are hereby incorporated by reference.

### FIELD OF THE INVENTION

The present invention relates in general to power supplies and in particular, to a power supply providing rectified alternating current (RAC) to a load with an intervening alternate polarity alternating current (AC) pulse to the load.

### BACKGROUND OF THE INVENTION

A common attribute of electrical equipment, such as the surfaces of plasma electrodes and other non-electrode surfaces, is that such surfaces become detrimentally charged leading to unwanted arcing. Prior art attempts to address surface charging include U.S. Pat. No. 6,001,224. In the case of U.S. Pat. No. 6,001,224, charge buildup is periodically discharged by switching the output to ground by capacitor discharge through an inductor. This solution to charging has met with limited success owing to the inductive switching producing high voltage ringing and large amounts of high frequency noise. The high voltage ringing stresses power supply components and the high frequency noise makes the surrounding electrical equipment vulnerable to instabilities. The lifespan of electrical components exposed to these discharges is reduced.

Another prior art solution to surface charging includes the use of an AC power supply with a sinusoidal waveform current. By way of example, in magnetron sputtering applications, two magnetrons are connected across the output of a frequency generator with each sputter magnetron alternately being a cathode and then an anode for the other magnetron. This is termed Dual Magnetron Sputtering (DMS) and has been found an effective method to sputter insulating films such as SiO₂. The frequency range for these AC power supplies is typically 20-100 kHz.

While plasma operation with an AC power source delivering a sinusoidal waveform typically results in little or no RF noise beyond the fundamental frequency, an AC power source suffers from a reduced operational rate compared to the above-detailed DC switching discharge. For instance, in DMS, the two magnetrons are only alternately sputter depositing material and only when the voltage drops to a sufficiently negative value to support the plasma and as a result, sputter rate is reduced compared to a DC power source. Given that two magnetrons are needed in DMS, with the physical space and ancillary equipment requirements, the over process efficiency is reduced.

Thus, there exists a need for a power supply able to reverse bias to avoid arcing caused by charge buildup and limit radiofrequency (RF) noise. There further exists a need for such a power supply driving a plasma generator to provide higher throughput and limited anodic deposition.

### SUMMARY OF THE INVENTION

A process for powering an electrical load includes applying a rectified alternating current waveform across the load for a first time period with only a single power supply for at least two half cycles. At least one half cycle of an alternating current waveform of opposite polarity are then applied relative to the rectified direct current waveform across the load for a second time period. A rectified alternating current waveform is then again applied across the load for at least two half cycles for a third time period to power the electrical load. The rectified alternating current waveform is optionally applied with a direct current offset. A negative offset is well suited for powering a magnetron load. The alternating current waveform prevents arcing and undesirable discharge, but at the expense of sputter rate. In many instances, the alternating current waveform is limited to a single half cycle or at least a duration less than the time periods of rectified alternating current application, for example at least an order of magnitude less duration. The duration of the first time period is either random or preselected. Likewise, the duration of the second time period is also independently either random or preselected in duration.

A power supply for powering an electrical load is provided that includes an electrical rectifier circuit having each half cycle of a periodically varying electrical input being individually and selectively rectified to provide at least two rectified direct current half cycles followed by at least one half cycle of an opposite polarity relative to the at least two rectified alternating current half cycles, and followed by at least two additional rectified alternating current half cycles. The rectifier circuit is readily formed with a quartic assembly of transistors with a mirror plane of orientation parallel to a side of the quartic assembly for said transistors.

### BRIEF DESCRIPTION OF THE DRAWINGS

FIG. 1 is a plot of an inventive bipolar rectifier power supply relative to a direct current voltage bias and a grounded reference;

FIG. 2 is a schematic of an inventive bias configuration for dual magnetron sputtering;

FIG. 3 is a block diagram for a configuration of an inventive power supply;

FIG. 4 is a voltage plot of an inventive power supply depicting an output waveform of three negative half cycle waveforms and three positive half cycle waveforms relative to a potential control signal;

FIG. 5 is a voltage plot of an inventive power supply depicting an output waveform of three negative half cycle waveforms and one positive half cycle waveform relative to a potential control signal;

FIG. 6 is a bipolar rectifier circuit operative in an inventive power supply;

FIG. 7 is another bipolar rectifier circuit operative in an inventive power supply providing optional isolation as well as a center-tapped output reference;

FIG. 8A is a bipolar rectifier circuit operative in an inventive power supply that is similar to that of FIG. 7 yet reduces the voltage hold off requirement of the transistors used in the circuit while providing isolation, optional for ground references are also provided;

FIG. 8B is an isolated gate drive subcircuit for the circuit depicted in FIG. 8A; and

FIG. 9 is a bipolar rectifier circuit operative in an inventive power supply with an optional DC voltage bias float subcircuit providing adjustable DC bias to generate an output as provided for example in FIG. 1.

### DETAILED DESCRIPTION OF THE PREFERRED EMBODIMENTS

The present invention has utility as a power supply operative across a wide range of power outputs that delivers rectifier alternating currnet output to a load and periodically reverses bias thereby avoiding charge buildup and resulting manifestation of arcing. The inventive power supply, through inclusion of a bipolar rectifier circuit, is able to deliver a bipolar rectified output to a load without resorting to a second power supply or capacitive discharge through an inductor. As a result, an inventive power supply delivers current densities of a conventional direct current power supply absent high frequency ringing associated with capacitive discharge with simplified equipment. An inventive power supply is well suited for the inclusion of center-tapped output references, ground references, and direct current voltage bias capabilities. An inventive power supply is particularly well suited for driving a sputter magnetron load.

The present invention provides a device and a process for the creation of a power supply output waveform in which individual half cycles of input periodically varying waveforms are selectively and individually rectified. Representative of input power waveforms include sinusoidal, square, triangle waveforms, and combinations thereof. One of ordinary skill in the art will appreciate that waveform period and magnitude are immaterial to the present invention upon appropriate selection of suitable power supply components. By way of example, an inventive power supply readily is formed to deliver an output to a load having half cycles of a duration between 1 and 100 microseconds, and powers of between 100 W and 1 MW.

An inventive power supply and process used to power a sputtering magnetron or plasma enhanced CVD magnetron load have a number of desirable attributes, some of which are detailed herein. An insulating or semi-insulating film is readily deposited by this power supply in steady state operation because any charge buildup is removed during an intervening positive AC half cycles. The plasma process is also more efficient than with a convention AC power supply, with the duty cycle of the negative and positive half cycle being subject to user optimization. For instance, for a sputter magnetron process, the magnetron is readily operated in negative rectified alternating current mode for extended periods, efficient sputtering, and only occasionally switch to positive alternating current half cycles for cathodic discharging purposes. Additionally, with the use of a periodic and preferably, sinusoidal output waveforms higher order

RF noise generated by conventional pulsed output switching is limited. A simplified rectification circuit of an inventive power supply reduces the complexity of the resultant “pulsed” DC plasma power supply, as compared to conventional power supplies. Further, as the inventive power supply delivers a consistent periodic output, the stress to the power electronic components are limited, as compared to conventional capacitive discharge “pulsed” DC plasma power supply.

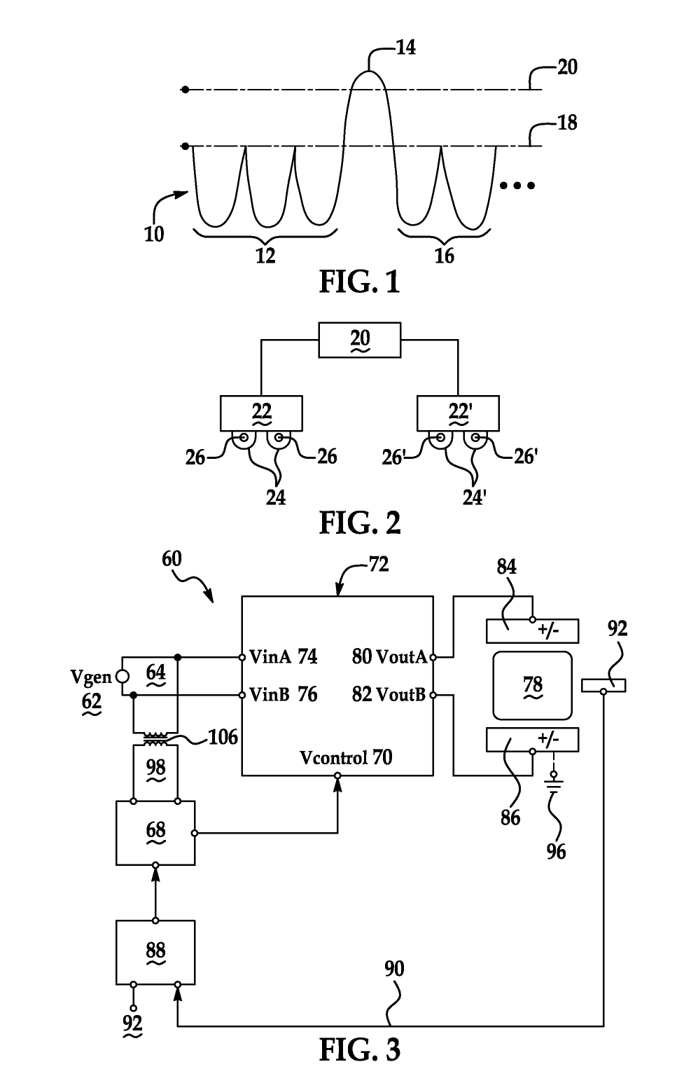

FIG. 1 is a plot of an exemplary output waveform shown generally at 10 where a number of half cycles are rectified 12 and a single positive pulse is selectively passed 14 followed by a number of rectified DC half cycles once again 16. The output waveform 10 is controlled to be either a rectified alternating current half cycle output 12 or 16 or an alternating current (AC) output 14. During the rectified alternating current output 12 or 16, the plasma load effectively sees a DC voltage. While the output waveform 10 is depicted with respect to a ground voltage bias 18, it is appreciated that by applying an offset voltage bias 20, it is appreciated that magnitude of the offset voltage bias affects the duration and magnitude of the polarity inversion between electrodes of the load. Based on specifics of the load, control of the offset voltage bias 20 serves to optimize the efficiency of load operation. It is further appreciated that a sensor monitoring an operational parameter of the load is readily provided to provide feedback for adjustment of the magnitude of offset voltage bias 20. While FIG. 1 depicts three rectified half cycles at 12 followed by a single opposite polarity pulse at 14 followed by a return to an unspecified number of rectified half cycles at 16, as denoted by the schematic of two rectified half cycles followed by three dots denoting continuation of the rectified half cycles, it is appreciated that the present invention provides for independent control of each half cycle of the periodic input waveform such that any single half cycle of an input waveform is either a rectified alternating current output or a comparative opposite polarity AC output in the output waveform. As such, a preselected number of rectified alternating current output half cycles are provided intermediate between alternating current half cycles of opposite polarity or, alternatively, the ratio in sequence between rectified alternating current half cycles and intermediate AC half cycle waveforms is randomized or dictated by a sensor monitoring the operational parameter of the load being driven by an inventive power supply. While the exemplary output waveform 10 is depicted with negative polarity rectified alternating current half cycles 12 and 16 with an intermediate positive AC half cycle 14, it is appreciated that these polarities are readily reversed, depending on load requirements.

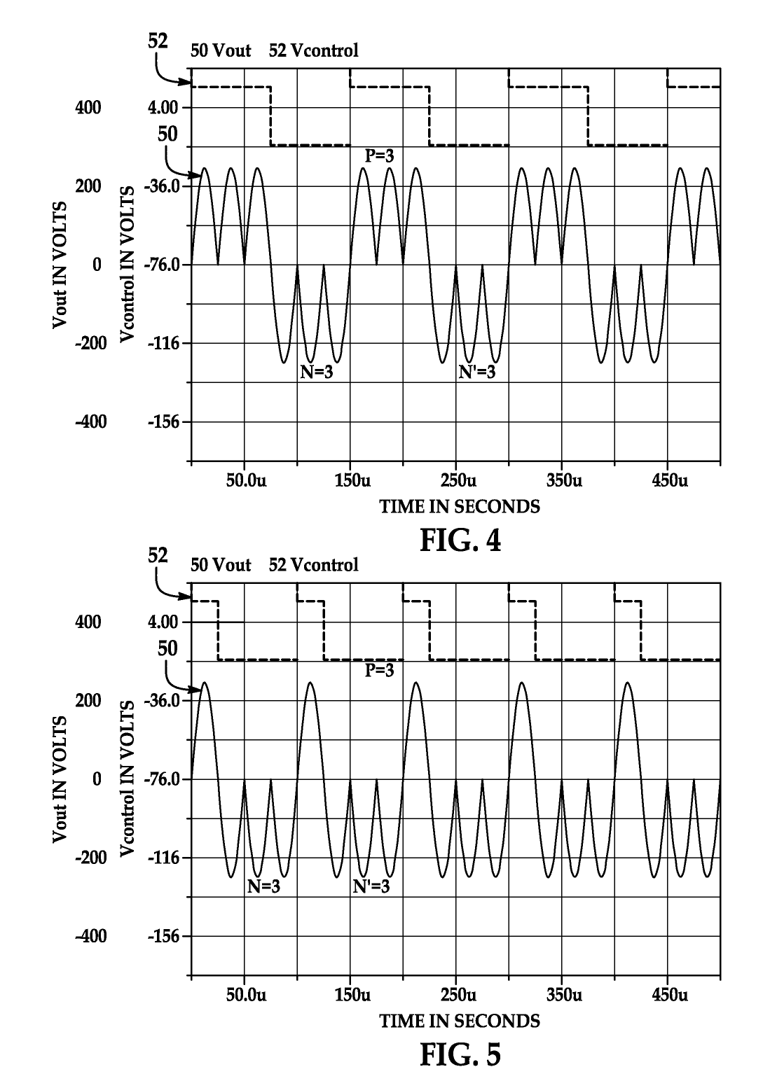

Other forms of an inventive power supply output waveform contain N number of DC rectified negative half cycles followed by P number of positive half cycles where 2<N<infinity and 1<P<infinity, or vice versa, followed by an independently chosen number N′ and P′ of alternating current rectified half cycles and positive half cycles, relative to N and P, respectively. FIG. 1 shows a potential waveform 10 where N=3 followed by P=1 followed by N′=2+an indeterminate additional (. . .) alternating current rectified negative half cycles. FIG. 4 shows a waveform 40 where N′=3 followed by P=3 followed by N=3. It is appreciated that N and P may change dynamically as needed by a particular process or may remain fixed producing a periodic pattern of negative and positive half cycles. FIG. 4 has an output waveform 40 where N=3, P=1, and N′=3, along with an associated control voltage 52 (dashed line). In this example, when the control voltage 52 is positive the inventive power supply is commanded to produce positive half cycles. Note that if the control voltage 42 or 52 remains high or low (P or N=infinity), the output 40 or 50, respectively, is fully rectified effectively presenting DC to the plasma. If N and P are both equal to 1, the control voltage alternates every half cycle and a pure AC periodic output waveform is produced.

In a sputtering application for instance, a sputter magnetron load operates as a cathode in rectified alternating current mode 12 or 16, sputtering efficiently. By periodically switching to an AC waveform 14, any charge built up on the cathode of the magnetron load of the sputter magnetron or on other surfaces is discharged. After one or more unrectified half cycle waveforms 14, the output 10 is returned to rectified alternating current mode 16. By preventing insulative coating deposition on the cathode, a sputter magnetron retains a high degree of deposition uniformity over time and achieves steady state operation over larger periods of time using a single power supply than previously attainable.

FIG. 2 is a schematic with an inventive power supply 20 connected to drive a dual sputter magnetron of magnetrons 22 and 22′. Each magnetron 22 and 24 supports a plasma 24 and 24′ adjacent to the electrodes 26 and 26′ that are cathodic when a negative alternating current rectified half cycle is applied thereto.

The output waveform to each magnetron 22 or 22′ is controlled to deliver a set number of positive or negative cycles as is best for the process, with the number of half cycles of a given polarity varied as desired. It is appreciated that one magnetron 22 is driven by more negative cycles than the other 22′ so the sputtering from the two magnetrons is not equal. By way of example, waveform 40 of FIG. 4 provides equivalent loading to each of the magnetrons 22 and 22′ while waveforms 10 or 50 of FIGS. 1 and 5, respectively, provide non-equal sputtering from magnetrons 22 and 22′, assuming equivalent vacuum conditions and deposition feedstocks.

An exemplary inventive power supply is shown generally at 60 in FIG. 3. The power supply 60 has an AC input source 62 that has a generator potential (Cgen). Optionally, the AC input source 62 is provided with a floating voltage bias 64. An inventive power supply 60 also has a control signal 66 produced by an isolated gate drive 68. The control signal 66 provides a control potential, Vcontrol 70 to a bipolar rectifier circuit 72. With the AC input source providing a channel A input voltage signal, VinA 74 and an input potential at channel B, VinB 76, waveform output is delivered to a load 78 as a waveform as depicted in any of FIGS. 1, 4 or 5 as a potential output across channels A and B, VoutA and VoutB at 80 and 82, respectively. It is appreciated that according to the present invention, the waveform delivered to the load 78 changes polarity on the electrodes denoted 84 and 86. An inventive power supply 60 is appreciated to be particularly useful in driving a sputtering magnetron as the load 78 as supported by electrodes 84 and 86. The waveform delivered across output channels 80 and 82 includes some number of positive periodic half cycles followed by a number of negative periodic half cycles across the load 78 as detailed above.

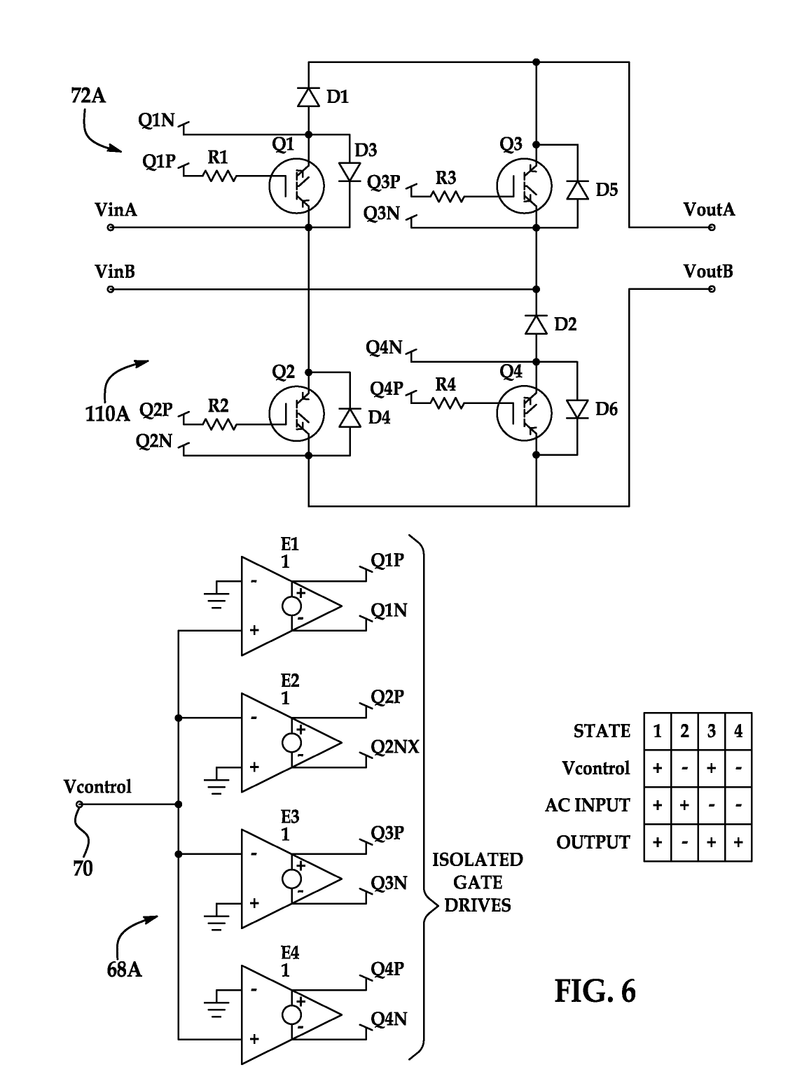

As will be detailed with respect to exemplary forms of circuit 72 per FIGS. 6-9, preferred transistors include insulated gate bipolar transistors (IGBTs) or MOSFETs, depending on the nature of the load 78. Optionally, a closed loop controller 88 receives an electrical signal 90 from a sensor 92. This signal 90 corresponds to an operational parameter of the load 78. In the instance where the load 78 is a sputtering magnetron, a sensor 92 provides a signal 90 correlating to a parameter of operation illustratively including voltage, optical plasma emission, gas partial pressure, arc condition, deposition film thickness, deposition film quality, or combination thereof. The closed loop controller 88 receives a signal 90 as an input, if such a controller is present, and compares the signal 90 to a preselected operational range set point or equation 92. Based on a comparison between the signal 90 and preselected values 92, the closed loop controller 88 provides a control signal 94 to the gate drive logic 68 to modify at least one parameter of N, P, N′, P′ or the offset voltage bias, synonymously referred to herein as a voltage float. Optionally, electrode 86 across the load 78 is provided with an earth ground 96. It is appreciated that an optional synchronization signal 98 is provided across inductor 100 so as to synchronize the waveform across output channels 80 and 82 with the phase of the AC input source 62.

Exemplary bipolar rectifier circuits 72 are illustrated in FIGS. 6, 7, 8A, and 9. FIG. 6 is a bipolar rectifier circuit 72A where insulated gate bipolar transistors (IGBTs) are used to form the active rectification circuitry 110A while Vcontrol 70 is the other portion of 72A. Each IGBT or MOSFET is denoted as Q where m=1, 2, 3 or 4; each diode is denoted as Dn where n=1-6; each resistor is denoted as Rm; and each gate is denoted by Em. The table 112 of FIG. 6 shows the potential states of the control voltage 70′ for the gate drives 68A, the phase of the input half cycle, and the resulting phase of the output half cycle. During State 1, Q1, D1, Q4 and D2 conduct, producing a positive half cycle output on VoutA 80 with respect to VoutB 82. In State 2, Q2 and Q3 conduct, producing a negative half cycle output on VoutA 80 with respect to VoutB 82. In States 3 and 4, D5 and D4 conduct, producing a positive output half cycle on VoutA 80 with respect to VoutB 82. The circuit 72A can produce any number of positive cycles P or P′ for each negative cycle N or N′ that is produced. This particular embodiment is limited though, in that it cannot produce multiple negative cycles without at least one interleaving positive cycle. This circuit does offer the advantage of a rather simple implementation. Bipolar rectifier circuit 72A generates N negative half cycles per every positive half cycle, where 2<N<infinity. It is appreciated that for Vgen frequencies greater than ˜75 kHz replace Q1, Q2, Q3 and Q4 IGBTs with MOSFETS of like quartic orientation. It is noted that the quartic assembly of IGBTs or MOSFETs of 110A has a horizontal mirror plane in FIG. 6 with the exception of signal joining diodes D1 and D2.

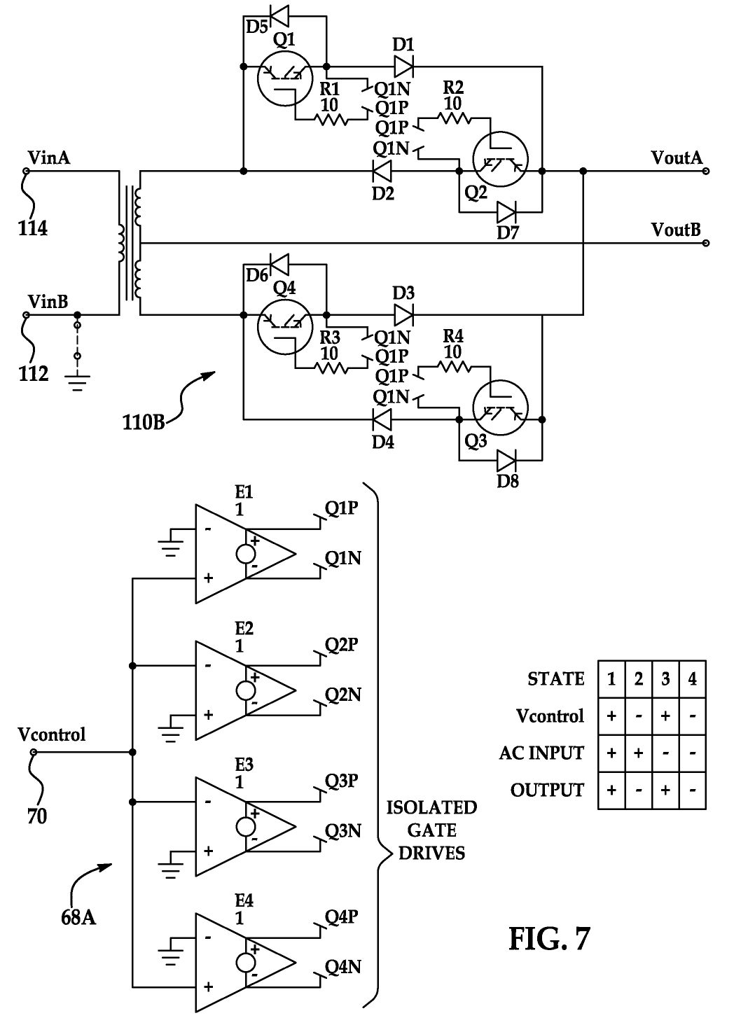

FIG. 7 depicts an alternate bipolar rectifier circuit 72, denoted as 72B, where an arbitrary number of N negative and P positive pulses are produced, where symbols have like meaning with respect to FIG. 6. In State 1, Q1 and D1 conduct, producing a positive output half cycle on VoutA 80 with respect to VoutB 82. In State 2, Q3 and D4 conduct, producing a negative output half cycle on VoutA 80 with respect to VoutB 82. In State 3, Q4 and D3 conduct, producing a positive output half cycle on VoutA 80 with respect to VoutB 82. Finally in State 4, Q2 and D2 conduct, producing a negative output half cycle on VoutA 80 with respect to VoutB 82. This is summarized in the FIG. 7 table. The bipolar rectifier circuit 72B generates N negative half cycles followed by positive half cycles where 2<N<infinity and 1<infinity. For Vgen frequencies greater than 75 kHz preferably one replaces Q1, Q2, Q3 and Q4 IGBTs with MOSFETs of like quartic orientation. The active rectification circuitry 110B has a quartic assembly of IGBTs or MOSFETs with a vertical mirror plane. An optional ground 112 is provided across VinB 76. Also, an optional center-tapped output reference is provided at 114. This embodiment, although slightly more complex, allows for an arbitrary number of P positive and N negative half cycles on the output.

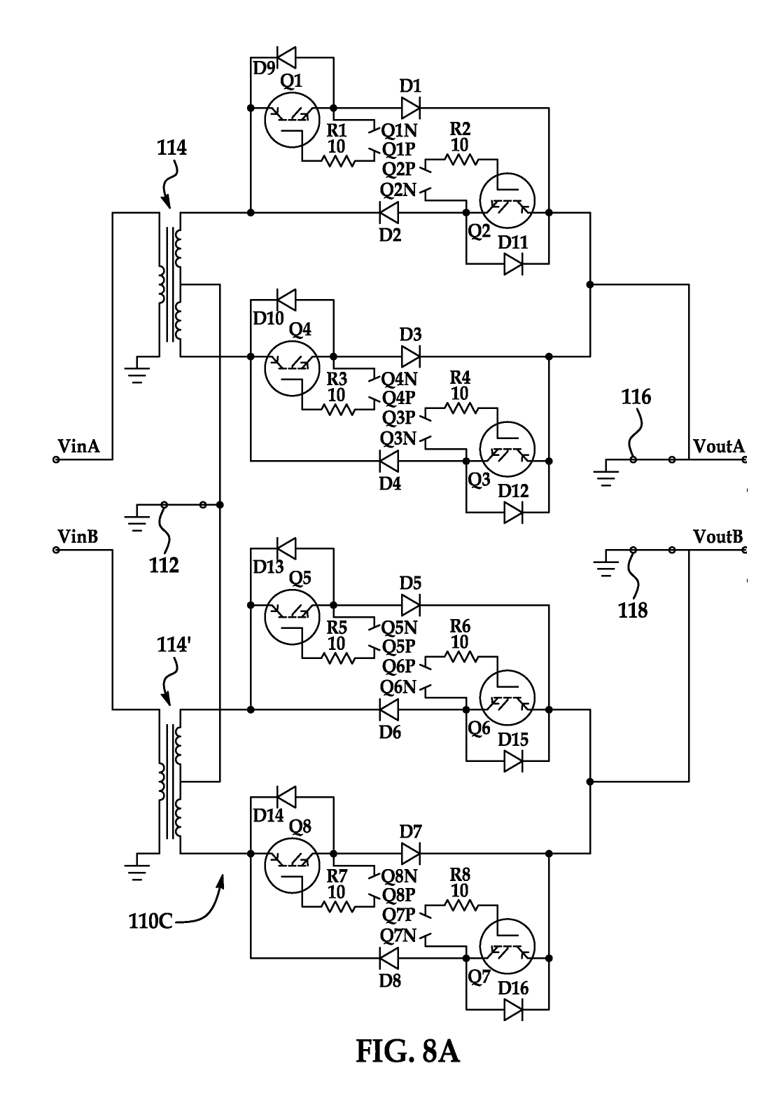

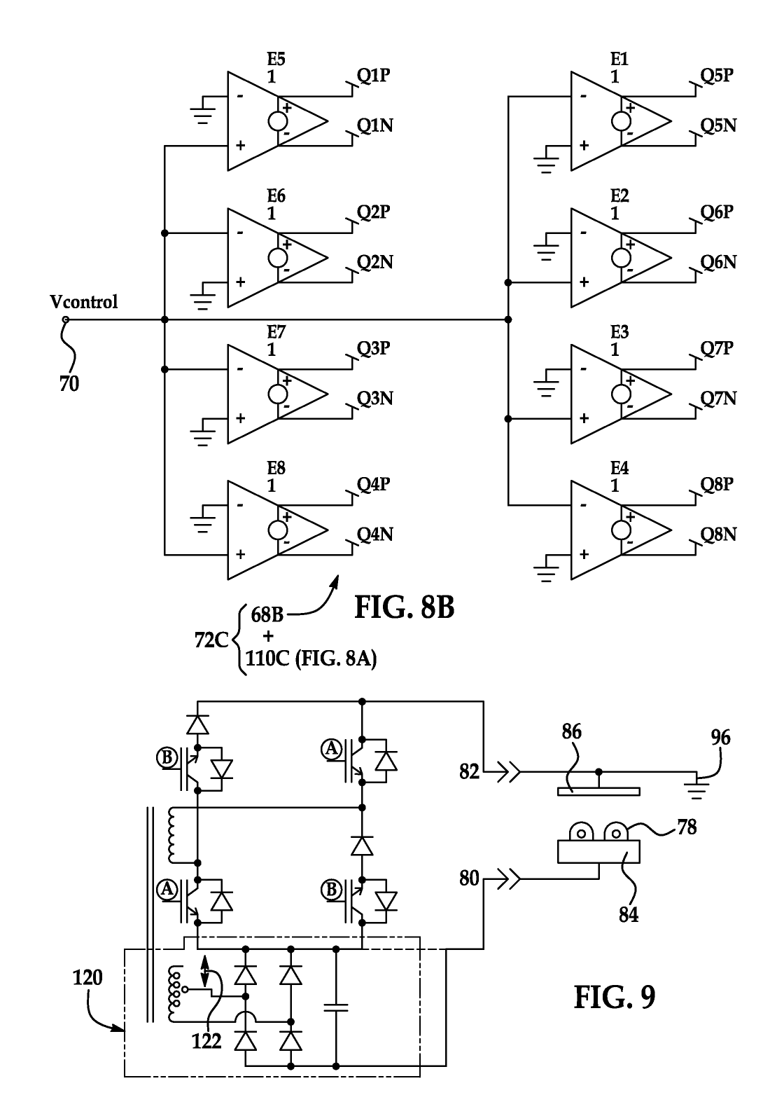

FIGS. 8A and 8B depict a rectifier circuit 72 functionally identical to FIG. 7 with the exception that lower reverse breakdown voltage parts may be used, which in some instances may reduce overall cost. In FIGS. 8A and 8B, like symbols have like meaning with respect to FIGS. 6 and 7 except that m=1-8 and n=1-14. The top and bottom half of the circuit 110C are duplicates of 100B and are driven out of phase with each other. For instance, during a positive input half cycle with a positive control voltage Q1, D1, Q7, and D8 conduct producing a positive output half cycle. For each potential conduction path, two transistors and diodes block voltage, effectively doubling the reverse breakdown voltage for each conduction path. Isolated gate drives 68B likewise duplicate isolated gate drive 68A. 110C (FIG. 8A) in combination with 68B (FIG. 8B) constitutes collectively bipolar rectifier circuit 72C. Optional grounds 116 are coupled to VoutA and VoutB, respectively.

An inventive process is implemented over a wide range of output frequencies. Typical mid-frequencies are from 20 kHz to 100 kHz. Higher operative frequencies extend from the 100s of kHz to RF. FIGS. 6, 7, 8, and 10 show such example circuits. The use of IGBTs in the example circuits is not required but is preferred for waveform outputs below 75 KHz. For higher frequencies the IGBTs are preferably replaced with MOSFETS.

The output can be centered on ground or can be floated relative to ground. The potential impact on the waveform with respect to ground is illustrated in FIGS. 1 at 18 and 20. The floating plasma potential can determine the DC bias of the output when the output is floated with respect to ground. This can increase the efficiency of the process during rectified operation.

The DC bias of the output of an inventive power supply is optionally floated at a controlled bias potential as shown in FIG. 9 utilizing the illustrated optional DC float circuit 120 where the DC bias level is adjusted by selecting a position on the secondary of the transformer 12.

In the context of plasma deposition, an inventive power supply is to be used for a range of plasma loads including sputter magnetrons and plasma CVD sources. The output power is readily designed for loads from the 100-500 W range to the hundreds of kW.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process for powering an electrical load comprising:
applying a rectified alternating current waveform across the load for a first time period with only a single power supply for at least two half cycles;
then applying at least one half cycle of an alternating current waveform of opposite polarity relative to said rectified alternating current waveform across the load from said power supply for a second time period; and
applying a second rectified alternating waveform across the load from said power supply for at least two half cycles for a third time period to power the electrical load.

2. The process of claim 1 wherein said rectified alternating current waveform has a direct current offset.

3. The process of claim 2 wherein said direct current offset is a negative voltage bias offset.

4. The process of claim 1 wherein said alternating current waveform of opposite polarity relative to said rectified alternating current waveform is provided for only one single half cycle.

5. The process of claim 1 wherein the first time period and the third time period are both greater than the second time period.

6. The process of claim 5 wherein the first time period and the third time period are at least an order of magnitude greater than the second time period.

7. The process of claim 1 wherein the electrical load is a sputter magnetron.

8. The process of claim 7 wherein the sputter magnetron is a dual magnetron sputtering system.

9. The process of claim 1 wherein the electrical load is a plasma enhanced chemical vapor deposition source or an ion source.

10. The process of claim 1 wherein the second time period is initiated after a random duration of the first time period.

11. The process of claim 10 wherein the second time period has a random duration.

12. The process of claim 1 wherein the second time period is initiated after a preselected temporal extent of the first time period.

13. The process of claim 12 wherein the second time period has a preselected duration.

14. A power supply for powering an electrical load comprising:
an electrical rectifier circuit having each half cycle of a periodically varying electrical input is individually and selectively rectified to provide at least two rectified alternating current half cycles followed by at least one half cycle of an opposite polarity relative to said at least two rectified alternating current half cycles, and followed by at least two rectified alternating current half cycles.

15. The power supply of claim 14 wherein said rectifier circuit comprises a quartic assembly of transistors with a mirror plane of orientation parallel to a side of the quartic assembly for said transistors.

16. The power supply of claim 14 further comprising an optional ground to said rectifier circuit.

17. The power supply of any of claims 14-16 wherein said transistors are insulated gate bipolar transistors or MOSFETS.

18. The power supply of claim 14 further comprising isolated gate drive logic.

19. The power supply of any of claims 14-16 further comprising a closed loop controller receiving a sensor signal and a set point and providing a control signal to said rectifier circuit.

20. The power supply of claim 18 further comprising a generator synchronization signal synchronizing said periodically varying electrical input with said at least two rectified direct current half cycles and said at least one half cycle of an opposite polarity relative to said at least two rectified direct current half cycles.
